(19) United States
(12) Patent Application Publication
(10) Pub. No.: US 2005/0122796 A1
(43) Pub. Date: Jun. 9, 2005

(54) Delayed locked loop in semiconductor memory device and its control method

(76) Inventors: Hea-Suk Jung, Ichon-shi (KR); Jong-Tae Kwak, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/876,426

(22) Filed: Jun. 25, 2004

(30) Foreign Application Priority Data
Dec. 4, 2003 (KR) 2003-87567

(51) Int. Cl. G11C 7/00

(52) U.S. Cl. 365/194

(57) ABSTRACT

A delayed locked loop in a semiconductor memory device includes a read enable signal generating block for generating a read enable signal, wherein the read enable signal is enabled based on the application of a read command, and is disabled when all data is read out and outputted; a first internal clock controlling block for intermitting the output of a first internal clock through the use of the read enable signal; a second internal clock controlling block for intermitting the output of a second internal clock through the use of the read enable signal; a DLL clock generating block for receiving the first and second internal clocks to thereby generate first and second DLL clocks.

### FIELD OF THE INVENTION

The present invention relates to a delayed locked loop in a semiconductor memory device; and, more particularly, to a delayed locked loop which is capable of generating an internal clock produced at the delayed locked loop only during read operation, thereby reducing an operation current.

### DESCRIPTION OF PRIOR ART

In general, clocks in a system or a circuit are used as a reference for adjusting an operating timing, or used to ensure more faster operations without error. When clocks provided externally are used in an internal circuit, a time delay (clock skew) by the internal circuit is occurred. A delayed locked loop (“DLL”) is employed to compensate the time delay thereby allowing the internal clock to have the same phase as the external clock. Specifically, the DLL matches a timing at which sensed data is outputted via a data output buffer, with a timing at which clocks are inputted externally, through the use of the external clock.

A description will be made as to the case where a DLL is applied to SDRAM according to the prior art, for example.

In FIG. 1, there is shown a block diagram of a resistor-controlled DLL of DDR SDRAM according to the prior art. The DLL comprises a first clock buffer 111, a second clock buffer 112, a clock divider 113, first to third delay lines 114, 115 and 116, a shift resistor 117, a shift controller 118, a phase comparator 119, first and second DLL drivers 120 and 121, and a delay model 122.

A detailed description will be made as to functions and operations of the above mentioned components.

The first clock buffer 111 receives an external inverted clock/clk to produce a first internal clock fall_clk which is generated in synchronism with a fall edge of an external clock clk.

The second clock buffer 112 receives the external clock clk to produce a second internal clock rise_clk which is generated in synchronism with a rising edge of the external clock clk.

The clock divider 113 divides the internal clock rise_clk by 1/n to output a delayed monitoring clock dly_in and a reference clock ref, wherein n is a positive integer and n=8 typically.

The first DLL driver 120 drives the output ifclk from the first delay line 114 to produce a DLL clock fclk_dll, and the second DLL driver 121 drives the output irclk from the second delay line 115 to produce a DLL clock rclk_dll.

The delay model 122 receives the output feedback_dly from the third delay line 116, to thereby allow the clock feedback_dly to undergo the same delay condition as an actual clock path.

The phase comparator 119 compares a phase of a rising edge of the feedback clock feedback outputted from the delay model 122 and that of a rising edge of the reference clock ref.

The shift controller 118, in response to a control signal ctrl outputted from the phase comparator 119, outputs shift control signals SR, SL, for shifting a clock phase of the first to third delay lines, or a delayed locked signal dll_lockb which represents that a locking is accomplished.

The shift resistor 117, in response to the shift control signals SR, SL outputted from the shift controller 118, allows resistors to operate and adjusts a delay amount of the first delay line 114 with the internal clock fall_clk as its input, the second delay line 115 with the internal clock rise_clk as its input, and the third delay line 116 with the delayed monitoring clock dly_in as its input.

Herein, the delay model 122 includes a dummy clock buffer, a dummy output buffer and a dummy load, and is referred to as a replica circuit. The shift resistor 117 and the shift controller 118 in the DDL are referred to as a delayed control signal generating block 123 for controlling the first to third delay lines 114, 115 and 116 in a delay block 110.

Referring to FIG. 2, there is shown a clock timing chart which illustrates the operation of the conventional resistor-controlled DLL with the above mentioned architecture.

The first clock buffer 111 generates the internal clock fall_clk that is synchronous with the falling edge of the external clock clk, and the second clock buffer 112 generates the internal clock rise_clk that is synchronous with the rising edge of the external clock clk. The clock divider 113 divides the internal clock rise_clk that is synchronous with the rising edge of the external clock clk by 1/n, to produce clocks ref and dly_in, that are synchronous with the external clock clk once per each nth clock.

In an initial operation, the delayed monitoring clock dly_in passes through only unit delay element of the third delay line 116 in the delay block ODT buffer 110 and is outputted as the clock feedback_dly, and then the clock is delayed at the delay model 122 and outputted as the feedback clock.

Meanwhile, the phase comparator 119 compares a rising edge of the feedback clock and that of the reference clock ref to produce a control signal ctrl. The shift controller 118, in response to the control signal ctrl, outputs shift control signals SR, SL, for controlling a shift direction of the shift resistor 117. The shift resistor 117, in response to the shift control signals SR, SL, determines the delay amounts of the first to third delay lines 114, 115 and 116. In this case, the resistor is shifted toward right according to input of the shift control signal SR, and toward left according to input of the shift control signal SL.

Thereafter, comparing of the feedback clock of controlled delay with the reference clock is performed, and the locking is accomplished at an instant that the two clocks have a minimum jitter. Specifically, a time difference between a clock provided externally and an internal operating clock is compensated, thereby allowing the DLL clock, fclk_dll and rclk_dll, which operate internally, to operate in synchronism with the external clock through an internal delay.

The DLL clocks, fclk_dll and rclk_dll produced by the DLL operation are needed only during read operation of data stored in the DRAM. Data outputting is performed when a read command is applied and then CL (“CAS Latency”) is elapsed, in response to the DLL clocks fclk_dll and rclk_dll produced at the DLL.

Referring to FIG. 3, there is an illustrative clock timing chart. First, the application of an active command enables a row address. Thereafter, the application of a read command enables a column address. Next, if CAS latency is elapsed, i.e., if three clocks are elapsed after the read command, data that is synchronous with the DLL clocks fclk_dll and rclk_dll is outputted.

Unfortunately, the prior art suffers from the disadvantages that the DLL clocks fclk_dll and rclk_dll are generated without interruption even after the read operation using the DLL clocks fclk_dll and rclk_dll, similarly to the external clock, as shown in FIG. 3. As a result, the prior art causes a necessary current consumption.

### SUMMARY OF INVENTION

It is, therefore, a primary object of the present invention to provide a delayed locked loop in semiconductor memory device and its control method, which allow an internal clock produced at a delayed locked loop to be outputted only during read operation, thereby eliminating an operation current.

In accordance with a preferred embodiment of the present invention, there is provided a delayed locked loop in a semiconductor memory device including a read enable signal generating block for generating a read enable signal, wherein the read enable signal is enabled based on the application of a read command, and is disabled when all data is read out and outputted; a first internal clock controlling block for intermitting the output of a first internal clock through the use of the read enable signal; a second internal clock controlling block for intermitting the output of a second internal clock through the use of the read enable signal; a DLL clock generating block for receiving the first and second internal clocks to thereby generate first and second DLL clocks.

In accordance with another preferred embodiment of the present invention, there is provided to a delayed locked loop in a semiconductor memory device, which comprises: a read enable signal generating means for generating a read enable signal, wherein the read enable signal is enabled based on the application of a read command, and is disabled when all data is read out and outputted; an external inverted clock controlling means for intermitting the output of an external inverted clock provided externally,.through the use of the read enable signal; and an external clock controlling means for intermitting the output of an external clock provided externally, through the use of the read enable signal.

In accordance with still another preferred embodiment of the present invention, there is provided to a delayed locked loop in a semiconductor memory device, which comprises: a read enable signal generating means for generating a read enable signal, wherein the read enable signal is enabled based on the application of a read command, and is disabled when all data is read out and outputted; a first delay line output clock controlling means for intermitting the output of a first delay line, through the use of the read enable signal; and a second delay line output clock controlling means for intermitting the output of a second delay line, through the use of the read enable signal.

Preferably, the read enable signal generating means outputs a read enable signal, wherein the read enable signal is initialized to a first logic state by a power-up signal prior to stabilization of power supply, enabled to a second logic state when a read command is applied externally, and is disabled to the first logic state after outputting of all data.

In accordance with still another preferred embodiment of the present invention, there is provided to a method for controlling a delayed locked loop, comprising the steps of: (a) holding a first node at a first logic state prior to the stabilization of power supply after application; (b) transiting the first node to a second logic state based on a read command provided externally; (c) holding the first node at the second logic state at a predetermined time period; (d) transiting the first node to the first logic state in response to a falling edge of signal for turning off an output driver; and (e) transiting the first node to the first logic state in response to the falling edge of the signal for turning off the output driver; and then holding the first node at the first logic state.

In accordance with still another preferred embodiment of the present invention, there is provided to a method for controlling a delayed locked loop, comprising the steps of: (a) outputting a read enable signal Read, the read enable signal being initialized to a first logic state by a power-up signal prior to stabilization of power supply, being enabled to a second logic state when a read command is applied externally, and being disabled to the first logic state after outputting of all data; (b) intermitting the output of a first internal clock through the use of the read enable signal; and (c) intermitting the output of a second internal clock through the use of the read enable signal.

### BRIEF DESCRIPTION OF DRAWINGS

The above and other objects and features of the present invention will become apparent from the following description of preferred embodiments given in conjunction with the accompanying drawings, in which:

FIG. 1 is a block diagram of a resistor-controlled DLL of DDR SDRAM according to the prior art;

FIG. 2 is a clock timing chart which illustrates the operation of the conventional resistor-controlled DLL;

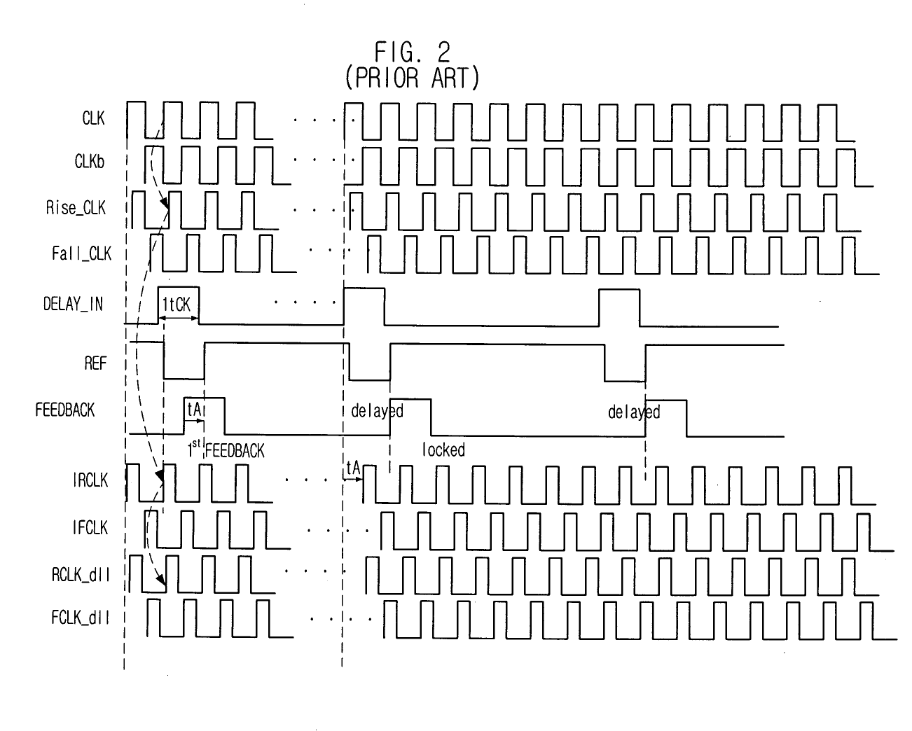

FIG. 3 is a an illustrative clock timing chart;

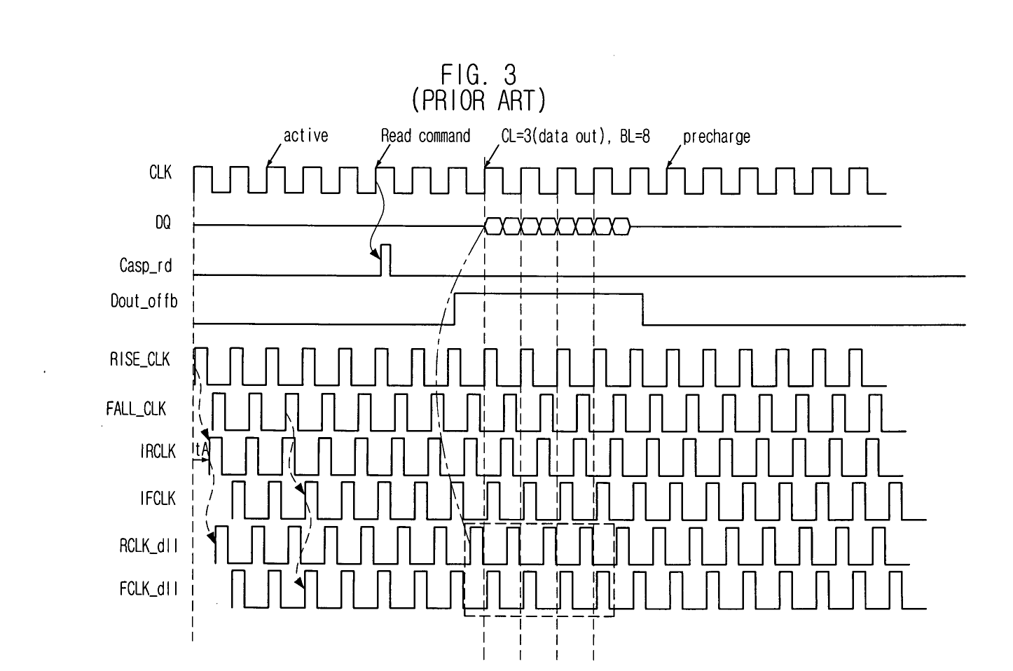

FIG. 4 is a schematic block diagram of a delayed locked loop in accordance with a preferred embodiment of the present invention;

FIG. 5 is a detailed circuit diagram of the read enable signal generating block shown in FIG. 4;

FIG. 6 is a detailed circuit diagram of the first and second internal clock controlling blocks 440f, 440r shown in FIG. 4; and

FIG. 7 is a clock timing chart in accordance with the present invention.

### DETAILED DESCRIPTION OF THE INVENTION

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of this invention. Accordingly, the description which follows is to be understood as being a broad, teaching disclosure directed to persons of skill in the appropriate arts, and not as limiting upon the present invention.

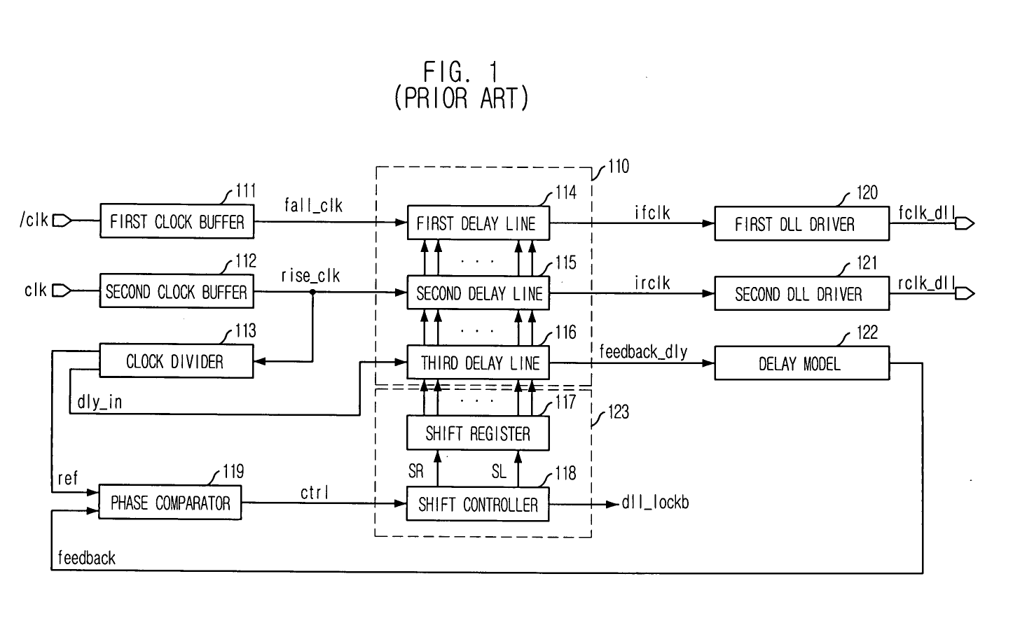

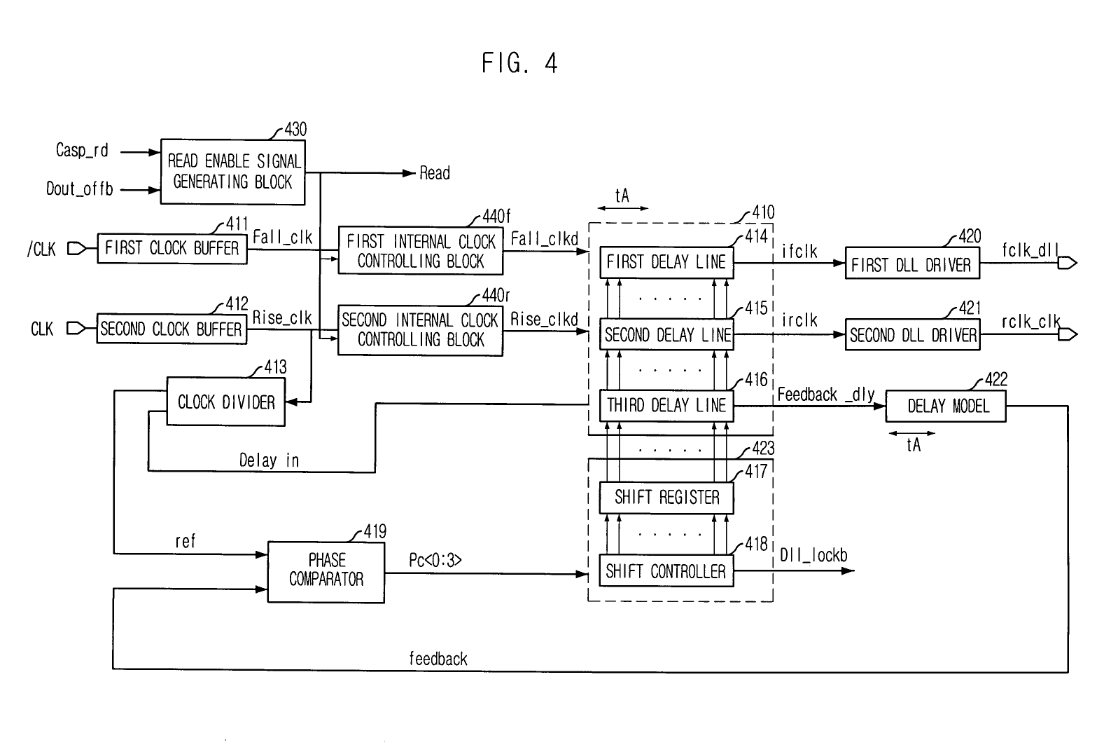

FIG. 4 is a schematic block diagram of a delayed locked loop in accordance with a preferred embodiment of the present invention. The configuration of FIG. 4 is identical to major components in the prior art shown in FIG. 1, except that the present invention includes a read enable signal generating block (Read_gen) 430 for generating a read enable signal, wherein the read enable signal is enabled based on the application of a read command and is disabled when all data is read out and outputted; a first internal clock controlling block (RD_ctrl) 440f for intermitting the output of the first internal clock fall_clk through the use of the read enable signal; and a second internal clock controlling block (RD_ctrl) 440r for intermitting the output of the second internal clock rise_clk through the use of the read enable signal.

Meanwhile, in accordance with another preferred embodiment of the present invention, in FIG. 4 the first and second internal clock controlling blocks 440f, 440r may be disposed at the front of the first and second clock buffers 411, 412, respectively. In accordance with still another preferred embodiment of the present invention, the first and second internal clock controlling blocks 440f, 440r may be disposed between the first and second delay lines 414, 415 and the first and second DLL drivers 420, 421, respectively.

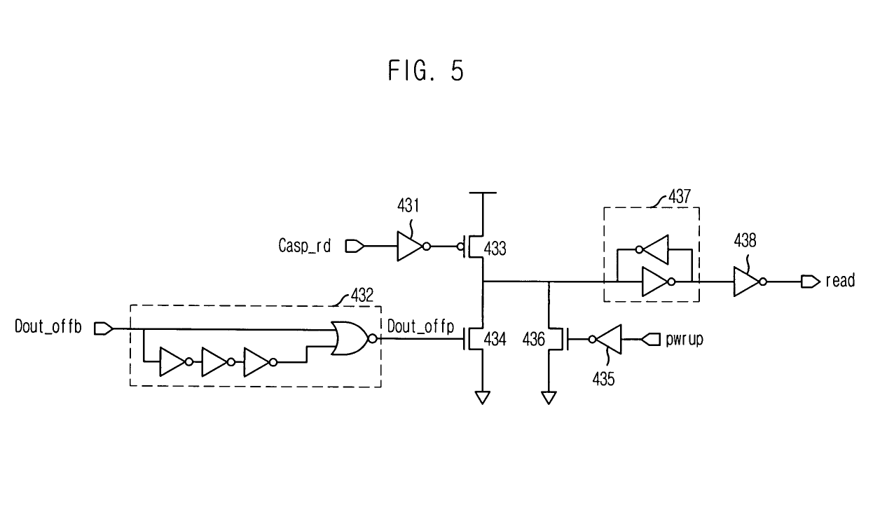

FIG. 5 is a detailed circuit diagram of the read enable signal generating block shown in FIG. 4.

The read enable signal generating block 430 outputs a read enable signal Read, wherein the read enable signal is initialized to a low level state by a power-up signal prior to stabilization of power supply, enabled to a high level state when the read command is applied externally, and is disabled to a low level state after outputting of all data.

To do this, a detailed circuit of the read enable signal generating block 430 includes: a first inverter 431 for inverting a read pulse signal Casp_rd inputted thereto; a first PMOS transistor 433 for outputting a power supply voltage using the output of the first inverter 431 as a control signal; a pulse generator 432 for generating an output driver off pulse signal Dout_offp of a high level state at a predetermined time period, in response to a falling edge of an output driver off bar signal Dout_offb; a first NMOS transistor 434 for outputting a ground voltage using the output driver off pulse signal Dout_offp as a control signal, wherein its drain is connected with the drain of the first PMOS transistor 434; a second inverter 435 for inverting a power-up signal inputted thereto; a second NMOS transistor 436 for outputting a ground voltage using the output of the second inverter 435 as a control signal, wherein its drain is connected with the drain of the first PMOS transistor 434; and a latch 437 where third and fourth inverters are invert-parallel connected each other.

Herein, a description will be made as to summary of the above mentioned signals.

The read pulse signal Casp_rd is a pulse-type signal, which is generated based on the read command provided externally.

The output driver off bar signal Dout_offb is one for allowing a data output driver to be switched to an operable mode at a high impedance state (cutoff state), wherein the data output driver receives a read command provided externally and outputs data according to a predefined CAS latency (“CL”) and a predefined burst length (“BL”) (8 data is consecutively outputted, if BL=8). Specifically, when the output driver off bar signal Dout_offb is in a high level state, the data output driver buffers data synchronous with the DLL clocks fclk_dll and rclk_dll and outputs the same externally. When the output driver off bar signal Dout_offb is in a low level state, the data output driver not receives internal data and data output value holds the high impedance state.

The power-up signal pwrup is one which transits from a low level state to a high level state if a power supply is applied and stabilized.

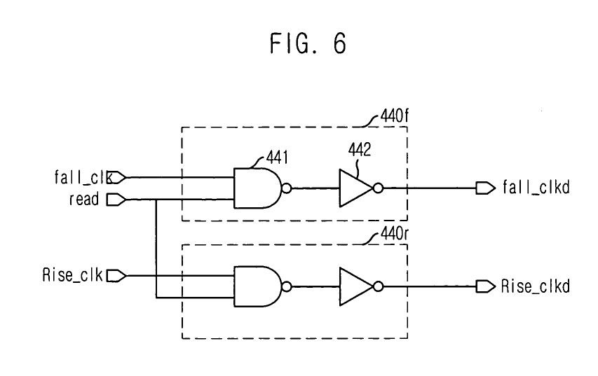

FIG. 6 is a detailed circuit diagram of the first and second internal clock controlling blocks 440f, 440r shown in FIG. 4.

The first internal clock controlling block 440f includes a first NAND gate 441 with the internal clock fall_clk and the read enable signal Read as its input, and an inverter 442 for inverting the output of the first NAND gate 441.

The second internal clock controlling block 440r is configurationally identical to the first internal clock controlling block 440f, except that it receives the second internal clock instead of the first internal clock.

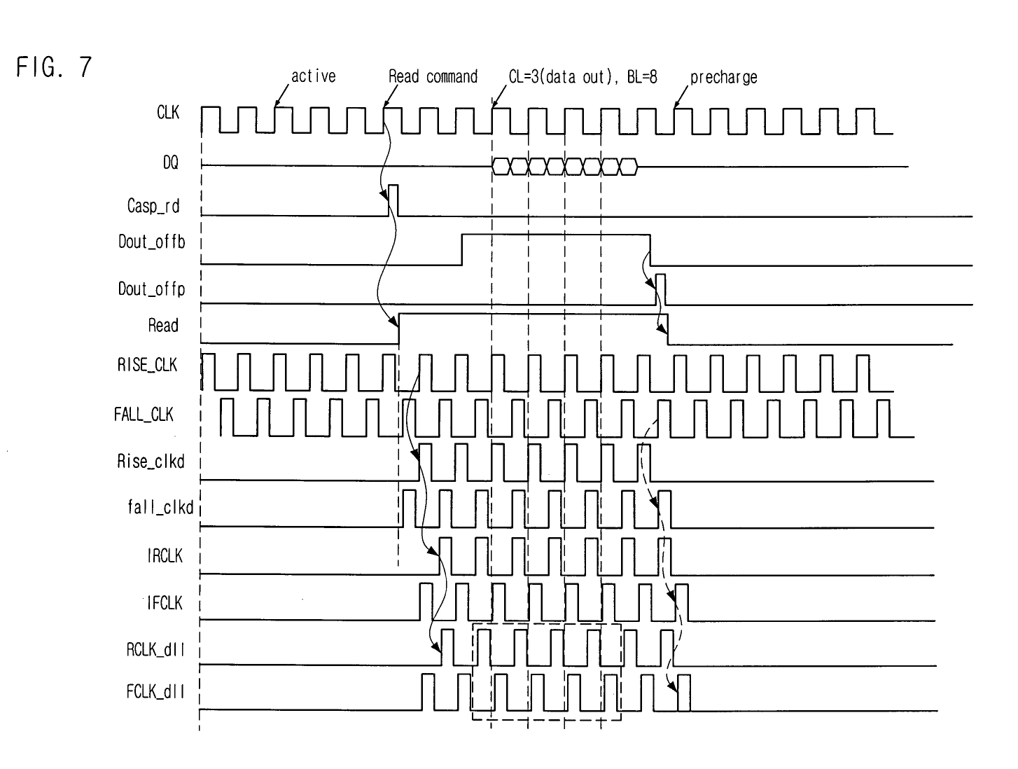

A detailed description will be made as to operations of the present invention using the clock timing chart of FIG. 7.

At step S1, the control process inverts a power-up signal pwrup of a low level state prior to the stabilization of power supply after application, and turns on the second NMOS transistor, thereby holding a node A at a low level state.

At step S2, the first PMOS transistor is turned on in response to the read pulse signal Casp_rd having a high level state based on the read command provided externally, thereby transiting a state of the node A to a high level state.

At step S3, if the read pulse signal Casp_rd is disabled, while the first PMOS transistor is turned off, the node A holds in a high level state by the latch 437.

At step S4, when the output driver off bar signal Dout_offb, which is generated responsive to a falling edge of the output driver off bar signal Dout_offb, is disabled, the process outputs the output driver off pulse signal Dout_offp of a high level state.

At step S5, the output driver off pulse signal Dout_offp of the high level state transits a state of the node A to a low level state.

At step S6, when the output driver off pulse signal Dout_offp transits to a low level state, the first NMOS transistor is turned off and the node A holds in the low level state by the latch.

In this way, the read enable signal Read is produced. Thus, the first and second internal clocks Fall_clk, Rise_clk are outputted through the first and second internal clock controlling blocks 440f, 440r, respectively, only when the read enable signal Read is in a high level state.

Therefore, the present invention has the ability of allowing clocks from a delayed locked loop to be outputted only when a particular operation is performed, thereby eliminating a DLL current consumption. Further, when a clock controlling block is disposed at the front of first and second delay lines, the present invention has the ability of preventing first and second delay lines and first and second DLL drivers, which occupies above 50 percentages of the DLL current consumption, from being driven at a unnecessary interval, thereby further eliminating a DLL current consumption.

The present application contains subject matter related to Korean patent application No. 2003-87567, filed in the Korean Patent Office on Dec. 4, 2003, the entire contents of which being incorporated herein by reference.

While the present invention has been described with respect to the particular embodiments, it will be apparent to those skilled in the art that various changes and modification may be made without departing from the spirit and scope of the invention as defined in the following claims.

1. A delayed locked loop in a semiconductor memory device, comprising:
a read enable signal generating means for generating a read enable signal, wherein the read enable signal is enabled based on the application of a read command, and is disabled when all data is read out and outputted;
a first internal clock controlling means for intermitting the output of a first internal clock through the use of the read enable signal;
a second internal clock controlling means for intermitting the output of a second internal clock through the use of the read enable signal; and
a DLL clock generating block for receiving the first and second internal clocks to thereby generate first and second DLL clocks.

2. The delayed locked loop as recited in claim 1, further comprising:
a first clock buffer for receiving a first external clock and generating the first internal clock; and
a second clock buffer for receiving a second external clock and generating the second internal clock.

3. The delayed locked loop as recited in claim 2, wherein the DLL clock generating block includes:
a delay line block for delaying the first and second internal clocks by a predetermined amount to thereby generate first and second synchronized clocks;
a clock divider for dividing the second internal clock by a predetermined ratio and generating a dividend clock;
a delay modeling block for delaying the dividend clock by total delay amount of actual data and control signal paths and generating a feedback signal;
a phase comparing block for comparing a phase of the dividend clock with a phase of the feedback signal;
a delay control block for determining the predetermined amount; and
first and second DLL drivers for respectively receiving the first and second synchronized clocks and respectively generating the first and second DLL clocks.

4. The delayed locked loop of claim 1, wherein the first internal clock controlling means includes:
a first NAND gate with the first internal clock and the read enable signal as its input; and
an inverter for inverting the output of the first NAND gate.

5. The delayed locked loop of claim 2, wherein the external inverted clock controlling means includes:
a first NAND gate with the external inverted clock and the read enable signal as its input; and
an inverter for inverting the output of the first NAND gate.

6. The delayed locked loop of claim 3, wherein the first delay line output clock controlling means includes:
a first NAND gate with the first delay line output clock and the read enable signal as its input; and
an inverter for inverting the output of the first NAND gate.

7. The delayed locked loop of any of claims 6, wherein the read enable signal generating means outputs a read enable signal, wherein the read enable signal is initialized to a first logic state by a power-up signal prior to stabilization of power supply, enabled to a second logic state when a read command is applied externally, and is disabled to the first logic state after outputting of all data.

8. The delayed locked loop of claim 7, wherein the read enable signal generating means includes:
a first inverter for inverting a read pulse signal inputted thereto;
a first PMOS transistor for outputting a power supply voltage using the output of the first inverter as a control signal;
a pulse generator for generating a output driver off pulse signal of the second logic state at a predetermined time period, in response to a falling edge of an output driver off bar signal;
a first NMOS transistor for outputting a ground voltage using the output driver off pulse signal as a control signal, wherein its drain is connected with the drain of the first PMOS transistor;
a second inverter for inverting a power-up signal inputted thereto;
a second NMOS transistor for outputting a ground voltage using the output of the second inverter as a control signal, wherein its drain is connected with the drain of the first PMOS transistor; and
a latch where third and fourth inverters are invert-parallel connected each other.

9. A method for controlling a delayed locked loop, comprising the steps of:
(a) holding a first node at a first logic state prior to the stabilization of power supply after application;
(b) transiting the first node to a second logic state based on a read command provided externally;
(c) holding the first node at the second logic state at a predetermined time period;
(d) transiting the first node to the first logic state in response to a falling edge of signal for turning off an output driver; and
(e) transiting the first node to the first logic state in response to the falling edge of the signal for turning off the output driver; and then holding the first node at the first logic state.

10. A method for controlling a delayed locked loop, comprising the steps of:
(a) outputting a read enable signal Read, the read enable signal being initialized to a first logic state by a power-up signal prior to stabilization of power supply, being enabled to a second logic state when a read command is applied externally, and being disabled to the first logic state after outputting of all data;
(b) intermitting the output of a first internal clock through the use of the read enable signal; and
(c) intermitting the output of a second internal clock through the use of the read enable signal.
